(19) United States
(12) Patent Application Publication
(10) Pub. No.: US 2012/0162946 A1
(43) Pub. Date: Jun. 28, 2012

(54) ELECTRONIC DEVICE

(75) Inventor: CHUN-AN LAI, Tu-Cheng (TW)

(73) Assignee: HON HAI PRECISION INDUSTRY CO., LTD., Tu-Cheng (TW)

(21) Appl. No.: 12/981,487

(22) Filed: Dec. 30, 2010

(30) Foreign Application Priority Data
Dec. 24, 2010 (TW) 99145942

(51) Int. Cl. H05K 7/00

(52) U.S. Cl. 361/782; 361/760; 361/783

(57) ABSTRACT

An electronic device including a PCB, a first electronic component, and at least one second electronic component arranged on the PCB. A circuit layer is formed on the PCB. The first electronic component has at least two pins. The pins of the first electronic component are electrically connected to the circuit layer. The first electronic component engages with the PCB to define a chamber. The at least one second electronic component is received in the chamber and electrically connected to the circuit layer.

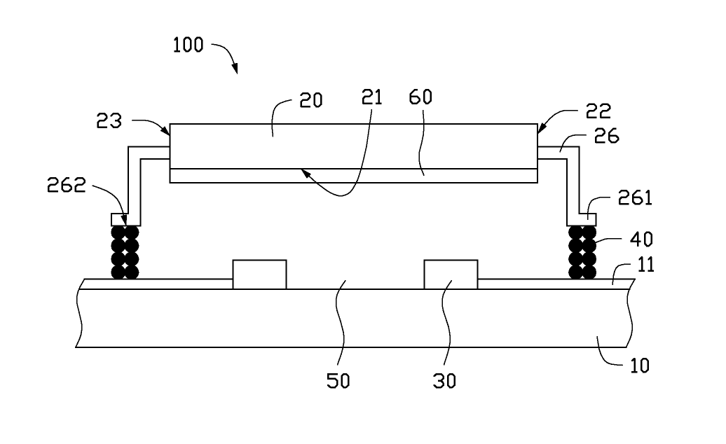

### BACKGROUND

1. Technical Field

The present disclosure generally relates to electronic devices.

2. Discussion of Related Art

An electronic device generally includes a printed circuit board (PCB) and a number of control chips arranged on the PCB. Other electronic components, such as resistors and capacitors are also included on the PCB. However, to mount more electronic components on the PCB, the size of the PCB must be big enough able to accommodate the more components or a bigger PCB must be used, therefore, the manufacturing cost of the PCB increases.

Therefore, what is needed is an electronic device, which can overcome the above described shortcomings.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

The FIGURE is a cross-sectional view of an electronic device in accordance with an embodiment of the present disclosure.

### DETAILED DESCRIPTION OF EMBODIMENTS

Referring to the FIGURE, an electronic device 100, in accordance with an embodiment is shown. The electronic device 100 includes a printed circuit board (PCB) 10, a first electronic component 20 and a plurality of second electronic components 30 arranged on the PCB 10, and a plurality of electric conductors 40.

A circuit layer 11 is formed on the PCB 10. The first electronic component 20 and the second electronic components 30 are arranged on the PCB 10 and are electrically connected to the circuit layer 11. In the present embodiment, the first electronic component 20 is a surface-mount type integrated chip, such as SO-8 electronic device. The first electronic component 20 has a surface 21 opposing the PCB 10, a first side surface 22 adjacent to the surface 21, and a second side surface 23 opposite to the first side surface 22. The first electronic component 20 has a plurality of pins 26. The pins 26 are arranged on the first side surface 22 and the second side surface 23. The pins 26 respectively extend from the first side surface 22 and second side surface 23 of the first electronic component 20, and a middle portion along a direction perpendicular to the first electronic component 20. A free end 261 of each pin 26 extends away from the first electronic component 20. The end 261 has a contact surface 262, which is a plane surface parallel to the surface 21 of the first electronic component 20. The contact surfaces 262 of the pins 26 electrically connect to the circuit layer 11.

The electric conductors 40 are respectively arranged between the pins 26 of the first electronic component 20 and the circuit layer 11. The electric conductor 40 electrically connects the contact surface 262 of the pin 26 and the circuit layer 11. The electric conductors 40 are made of metal, such as solder paste, copper, or silver.

The first electronic component 20 is electrically connected to the circuit layer 11, and is engaged with the PCB 10 to define a chamber 50. The second electronic components 30 are received in the chamber 50, and are arranged at the bottom of the first electronic component 20. In the present embodiment, the first electronic component 20 and the second electronic components 30 are spaced from each other. The second electronic components 30 are surface-mount type capacitors. In other embodiments, the second electronic component 30 can be only one, or any other number such as three, or more than three.

In the present embodiment, insulation materials 60 can be coated on the surface 21 of the first electronic component 20. In other embodiments, the insulation materials 60 can be coated on the one surface of the second electronic components 30, which is away from the circuit layer 11. In addition, thermal grease can be coated on the surface 21 of the first electronic component 20 and/or the surface of the second electronic components 30, which is away from the circuit layer 11.

In other embodiment, when the pins 26 are long enough, the pin 26 of the first electronic component 20 can be directly connected to the circuit layer 11 of the PCB 10, therefore, the first electronic component 20 engages with the PCB 10 to define a chamber 50 for receiving the second electronic components 30.

The first electronic component 20 engages with the PCB 10 to define a chamber 50 for receiving the second electronic component 30, therefore, the area of the PCB 10 can be reduced. Furthermore, the electronic components are arranged in ideal positions, to allow the electronic device to be stable during operations

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a printed circuit board (PCB) having a circuit layer thereon;
a first electronic component having at least two pins, the pins being electrically connected to the circuit layer, the first electronic component engaged with the PCB to define a chamber; and
at least one electronic component received in the chamber and electrically connected to the circuit layer of the PCB.

2. The electronic device of claim 1, wherein the first electronic component is a surface-mount type integrated chip.

3. The electronic device of claim 1, wherein the second electronic component includes a surface-mount type capacitor.

4. The electronic device of claim 1, further comprising a plurality of electric conductors, the pins of the first electronic component electrically connected to the circuit layer of the PCB via the electric conductors.

5. The electronic device of claim 1, wherein the electric conductor is selected from solder paste, copper, or silver.

6. The electronic device of claim 1, wherein the first electronic component and the second electronic component are spaced from each other.

7. The electronic device of claim 1, wherein an insulation material is arranged between the first electronic component and the second electronic component.

8. The electronic device of claim 1, wherein the insulation material is coated on one surface of the first electronic component which faces the PCB.

9. The electronic device of claim 1, wherein thermal grease is arranged between the first electronic component and the second electronic component.

10. The electronic device of claim 9, wherein the thermal grease is coated on one surface of the first electronic component which faces the PCB.
